(19) United States
(12) Patent Application Publication
(10) Pub. No.: US 2025/0150047 A1
(43) Pub. Date: May 8, 2025

(54) PARALLEL-SERIES COMBINER AND POWER AMPLIFIER INCLUDING THE SAME

(71) Applicant: SAMSUNG ELECTRONICS CO., LTD., SUWON-SI (KR)

(72) Inventors: Kyutaek Oh, Geumjeong-gu (KR); Ockgoo Lee, Geumjeong-gu (KR); Hyunchul Park, Suwon-si (KR); Hyunjin Ahn, Geumjeong-gu (KR); Sangmin Yoo, Suwon-si (KR); Jaeyeon Jeong, Suwon-si (KR); Joonhoi Hur, Suwon-si (KR)

(73) Assignee: Pusan National University Industry-University Cooperation Foundation, Geumjeong-gu (KR)

(21) Appl. No.: 18/907,160

(22) Filed: Oct. 4, 2024

(30) Foreign Application Priority Data
Oct. 6, 2023 (KR) 10-2023-0133778
Jan. 25, 2024 (KR) 10-2024-0011846

(51) Int. Cl. H03F 3/24; H01F 27/28; H03F 1/56

(52) U.S. Cl. CPC H03F 3/245; H01F 27/2804; H03F 1/565; H03F 2200/541

(57) ABSTRACT

A combiner includes a first unit combiner including a first primary winding connected to a first input terminal, a second primary winding connected to a second input terminal, and a first secondary winding having first and second end portions, the first end portion connected to an output terminal, wherein the first primary winding, the second primary winding, and the first secondary winding are stacked and form a first loop, a second unit combiner including a third primary winding connected to a third input terminal, a fourth primary winding connected to a fourth input terminal, and a second secondary winding having third and fourth end portions, the third end portion connected to the output terminal, wherein the third primary winding, the fourth primary winding, and the second secondary winding are stacked and form a second loop, and a third secondary winding connected between the first and fourth end portions.

### CROSS-REFERENCE TO RELATED APPLICATIONS

This application claims priority under 35 U.S.C. § 119 to Korean Patent Application No. 10-2023-0133778, filed on Oct. 6, 2023, and to Korean Patent Application No. 10-2024-0011846, filed on Jan. 25, 2024, both in the Korean Intellectual Property Office, the disclosures of which are incorporated by reference herein in their entireties.

### BACKGROUND

### 1. Technical Field

The present disclosure relates to a parallel-series combiner and a power amplifier including the parallel-series combiner.

### 2. Discussion of Related Art

Demand for a mobile communication technology with a higher data transmit rate and a low latency continues to increase. In particular, as 5-th generation (5-G) communication technologies using a millimeter wave spectrum are commercialized, studies and research are being conducted to support wireless communication in a high frequency band.

A power amplifier (PA) may be used to support millimeter wave communication. To couple several PAs, various transformer-based power combiners may be used. In particular, for the design of a high-power and high-efficiency PA in a millimeter wave communication system, a power combiner is used provide a low input impedance and low passive loss.

### SUMMARY

Embodiments of the present disclosure provide a parallel-series combiner and a power amplifier including the parallel-series combiner.

According to an embodiment of the present disclosure, a combiner includes a first unit combiner including a first primary winding connected to a first input terminal, a second primary winding connected to a second input terminal, and a first secondary winding having a (1-1)-th end portion and a (1-2)-th end portion, wherein the (1-1)-th end portion is connected to an output terminal, and having structure in which the first primary winding, the second primary winding, and the first secondary winding are stacked in a vertical direction and form a first loop, a second unit combiner including a third primary winding connected to a third input terminal, a fourth primary winding connected to a fourth input terminal, and a second secondary winding having a (2-1)-th end portion and a (2-2)-th end portion, wherein the (2-1)-th end portion is connected to the output terminal, and having a structure in which the third primary winding, the fourth primary winding, and the second secondary winding are stacked in the vertical direction and form a second loop, and a third secondary winding connected between the (1-2)-th end portion, which is opposite to the (1-1)-th end portion in the first primary winding, and the (2-2)-th end portion which is opposite to the (2-1)-the end portion in the second secondary winding.

According to an embodiment of the present disclosure, a power amplifier includes a power amplification stage including a first unit PA (power amplifier) cell, a second unit PA cell, a third unit PA cell, and a fourth unit PA cell, and a combiner connected to an output terminal of the power amplification stage, the combiner includes a first unit combiner which includes a first primary winding connected to the first unit PA cell, a second primary winding connected to the second unit PA cell, and a first secondary winding having a (1-1)-th end portion and a (1-2)-th end portion, wherein the (1-1)-th end portion is connected to an output terminal, and has a structure in which the first primary winding, the second primary winding, and the first secondary winding are stacked in a vertical direction and form a first loop, a second unit combiner which includes a third primary winding connected to the third unit PA cell, a fourth primary winding connected to the fourth unit PA cell, and a second secondary winding having a (2-1)-th end portion and a (2-2)-th end portion, wherein the (2-1)-th end portion is connected to the output terminal, and has a structure in which the third primary winding, the fourth primary winding, and the second secondary winding are stacked in the vertical direction and form a second loop, and a third secondary winding connected between the (1-2)-th end portion, which is opposite to the (1-1)-th end portion in the first primary winding, and the (2-2)-th end portion which is opposite to the (2-1)-the end portion in the second secondary winding.

According to an embodiment of the present disclosure, a power amplifier includes a power amplification stage including a first unit PA (power amplifier) cell, a second unit PA cell, a third unit PA cell, and fourth unit PA cells, a first phase shifter connected to an input terminal of the power amplification stage to shift an input signal from the power amplification stage by a specific phase, a first unit combiner including a first primary winding connected to the first unit PA cell, a second primary winding connected to the second unit PA cell, and a first secondary winding having a (1-1)-th end portion and a (1-2)-th end portion, wherein the (1-1)-th end portion is connected to a load terminal, in which the first primary winding, the second primary winding, and the first primary winding have a stack structure in a vertical direction and form a first loop, a second unit combiner including a third primary winding connected to the third unit PA cell, a fourth primary winding connected to the fourth unit PA cell, and a second secondary winding having a (2-1)-th end portion and a (2-2)-th end portion, wherein the (2-1)-th end portion is connected to the load terminal, in which the third primary winding, the fourth primary winding, and the second primary winding have a stack structure in the vertical direction and form a second loop, and a second phase shifter connected between the (1-2)-th end portion, which is opposite to the (1-1)-th end portion, in the first primary winding, and the (2-2)-th end portion, which is opposite to the (2-1)-th end portion, in the second secondary winding.

### BRIEF DESCRIPTION OF THE FIGURES

The above and other objects and features of the present disclosure will become apparent by describing in detail embodiments thereof with reference to the accompanying drawings.

FIG. 1 is a plan view of a combiner according to some embodiments.

FIG. 2 is an exploded perspective view of one unit combiner illustrated in FIG. 1.

FIG. 3 is a view illustrating the stack structure of a unit combiner according to some embodiments.

FIG. 4 illustrates a power amplifier according to some embodiments.

FIG. 5 illustrates an equivalent circuit of the power amplifier illustrated in FIG. 4.

FIG. 6 is a perspective view of a metal layer structure including a combiner according to some embodiments.

FIG. 7 is a plan view of the metal layer structure of FIG. 6.

FIG. 8 illustrates a power amplifier according to some embodiments.

FIG. 9 illustrates a simulation result for a passive element loss of a combiner according to some embodiments.

FIG. 10 illustrates a simulation result for a parallel resistance of a combiner according to some embodiments.

FIG. 11 illustrates a simulation result for an input impedance of a combiner according to some embodiments.

FIG. 12 illustrates a load-pull simulation result according to some embodiments.

FIG. 13 illustrates a simulation result of an S-parameter of the power amplifier according to some embodiments.

FIG. 14 illustrates a simulation result of a gain and a PAE of the power amplifier at a target frequency according to some embodiments.

FIG. 15 illustrates a power amplifier according to some embodiments.

FIG. 16 illustrates a power amplifier to which a phase shifter is added according to some embodiments.

FIG. 17 illustrates a wireless communication device according to some embodiments.

### DETAILED DESCRIPTION

Hereinafter, embodiments of the present disclosure are described clearly and in detail such that those skilled in the art may easily reproduce the present disclosure. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the spirit and scope of the inventive concepts. The same reference numerals are used for the same components in the drawings, and redundant descriptions of the same components may be omitted.

In the drawings, the thicknesses, the ratios, and the dimensions of the elements may be exaggerated for effective description of the technical contents.

According to the present specification, a direction in which a primary winding and a secondary winding of a combiner (or combiner) are stacked is defined as a vertical direction, a direction perpendicular to the vertical direction and extending toward an input terminal is defined as a first direction, and a direction symmetrical to the first direction and extending toward an output terminal is defined as a second direction. A direction perpendicular to the vertical direction may be referred to as a horizontal direction. For example, the first direction may be a horizontal direction. A direction perpendicular to the vertical direction, that is a horizontal direction, and crossing the first direction may be a third direction.

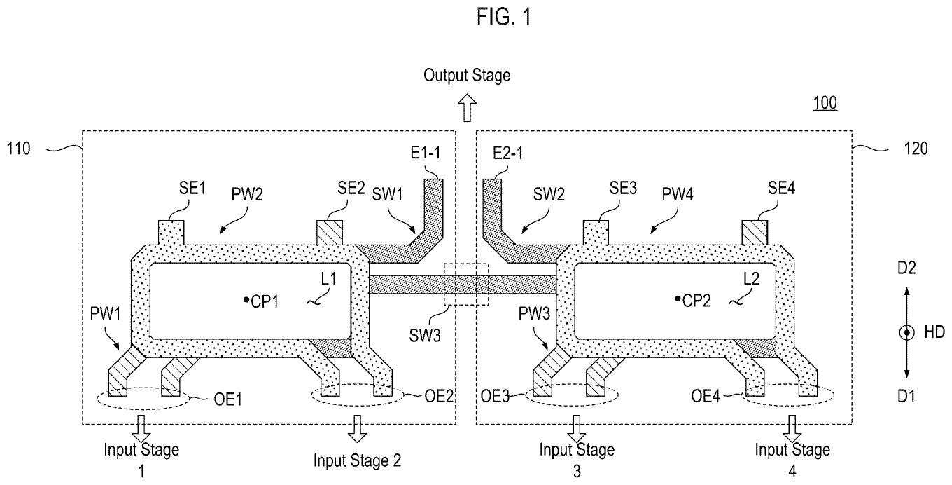

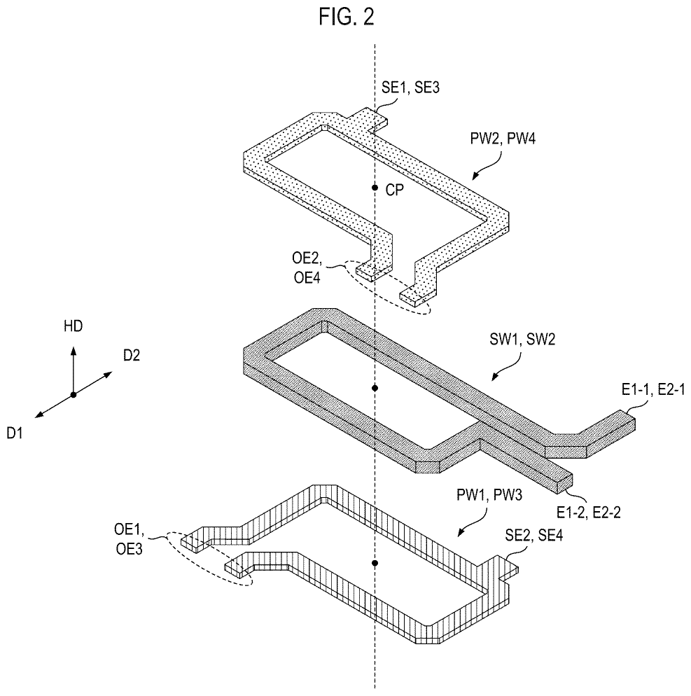

FIG. 1 is a plan view of a combiner according to some embodiments, and FIG. 2 is an exploded perspective view of one unit combiner illustrated in FIG. 1.

Referring to FIG. 1, a combiner 100 according to some embodiments may include a first unit combiner 110 and a second unit combiner 120.

The first unit combiner 110 may include a first primary winding PW1, a second primary winding PW2, and a first secondary winding SW1. The first unit combiner 110 may be implemented as a transformer in which two primary windings and one secondary winding are coupled in parallel. Referring to FIG. 1, the two primary windings may be implemented as the first primary winding PW1 and the second primary winding PW2, and the secondary winding may be implemented as the first secondary winding SW1.

The second unit combiner 120 may include a third primary winding PW3, a fourth primary winding PW4, and a second secondary winding SW2. The second unit combiner 120 may be implemented as a transformer in which two primary windings and one secondary winding are coupled to each other in parallel. Referring to FIG. 1, the two primary windings may be implemented as the third primary winding PW3 and the fourth primary winding PW4, and the secondary winding may be implemented as the second secondary winding SW2.

When the primary windings of the second unit combiner 120 are combined in parallel, which may be connected to the input terminal, an imbalance of parasitic capacitors, which may exist on the primary and secondary sides of the combiner 100, and a passive loss may decrease. The passive loss may be due to a loss of an output combiner or a matching network.

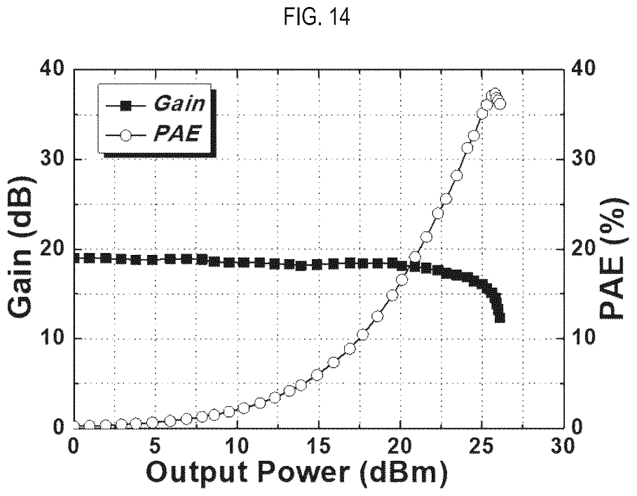

The first unit combiner 110 and the second unit combiner 120 may be connected to each other through the third secondary winding SW3. When the first unit combiner 110 and the second unit combiner 120 are connected to each other through the third secondary winding SW3, the first secondary winding SW1, the second secondary winding SW2, and the third secondary winding SW3 may form a secondary winding. The third secondary winding SW3 may be disposed at the same layer as the first secondary winding SW1 and the second secondary winding SW2 in a stack structure. For example, the first secondary winding SW1, the second secondary winding SW2, and the third secondary winding SW3 may be formed as a unitary secondary winding. Accordingly, the combiner 100 may be viewed as a stacked parallel-series combiner including unit combiners connected in series, and each unit combiner is formed by connecting two primary windings to one secondary winding in parallel. Accordingly, as the stacked parallel-series structure is provided, the combiner 100 according to the present disclosure may substantially cancel a parasitic capacitor component of components (e.g., unit PA (power amplifier) cells) based on imaginary component of the combiner 100, and may leave a parallel resistance component, which may have a high (e.g., maximum) output (see FIG. 14).

Each unit combiner, e.g., the first unit combiner 110 and the second unit combiner 120, may have the structure in which the windings are stacked in a vertical direction HD.

Referring to FIG. 2, according to some embodiments, the first unit combiner 110 of FIG. 1 may have a structure in which the first primary winding PW1, the second primary winding PW2, and the first secondary winding SW1 are stacked in the vertical direction HD. In this case, the first secondary winding SW1 may be interposed between the first primary winding PW1 and the second primary winding PW2. For example, the first primary winding PW1 may be disposed in the vertical direction HD with respect to the first secondary winding SW1, and the second primary winding PW2 may be disposed in a direction opposite to the vertical direction HD with respect to the first secondary winding SW1. Accordingly, the first secondary winding SW1 may be magnetically coupled (or inductively coupled) to the first primary winding PW1 and the second primary winding PW2.

The second unit combiner 120 of FIG. 1 may have the structure in which the third primary winding PW3, the fourth primary winding PW4, and the second secondary winding SW2 are stacked in the vertical direction HD. In this case, the second secondary winding SW2 may be interposed between the third primary winding PW3 and the fourth primary winding PW4. For example, the third primary winding PW3 may be disposed in the vertical direction HD with respect to the second secondary winding SW2, and the fourth primary winding PW4 may be disposed in the direction opposite to the vertical direction HD with respect to the second secondary winding SW2. Accordingly, the second secondary winding SW2 may be magnetically coupled (or inductively coupled) to the third primary winding PW3 and the fourth primary winding PW4.

According to some embodiments, the first primary winding PW1, the second primary winding PW2, and the first secondary winding SW1 may each have a center point CP and may be stacked in the vertical direction HD along a center line through the center points CP. In addition, the third primary winding PW3, the fourth primary winding PW4, and the second secondary winding SW2 may be stacked in the vertical direction HD along a respective center line.

According to some embodiments, the primary winding and the secondary windings may be formed to have a single turn (a turn number=1), as illustrated. Accordingly, the turn-ratio between the turn number of the first primary winding PW1 and the turn number of the first secondary winding SW1 may be 1:1, the turn-ration between the turn number of the second primary winding PW2 and the turn number of the first secondary winding SW1 may be 1:1, the turn-ratio between the turn number of the third primary winding PW3 and the turn number of the second secondary winding SW2 may be 1:1, and the turn-ratio between the turn number of the fourth primary winding PW4 and the turn number of the second secondary winding SW2 may be 1:1. In a case that the turn-ratio between the turn number of the primary winding and the turn number of the secondary winding is formed to be 1:1, the optimal load impedance may be applied to components (e.g., a power amplifier, etc.) connected to the primary winding.

When the combiner 100 is used in an ultra-high frequency range such as a millimeter wave band, the primary and secondary windings of each unit combiner, (which may be configured as a transformer, of the combiner 100 may be formed to have a physically short length and/or a low number of turns. Accordingly, in the millimeter band, the coupling factor of the combiner 100 may decrease.

When the windings are stacked in the vertical direction HD according to some embodiments, the combiner 100 may have a higher coupling factor, and the passive element loss may decrease.

According to some exemplary embodiments, as illustrated, each winding may have the form in which a portion of a closed loop (or a closed curve) is open. According to the present disclosure, an end portion of a winding may refer to a portion where each winding is terminated, and a plurality of end portions may be defined for each winding. Among the end portions, end portions corresponding to a partially open shape in a closed-loop shape of the winding may be defined as open end portions. In addition, an end portion extending from the winding to receive a supply voltage may be defined as a supply end portion. In addition, any end portion may be referred to as an end portion.

Returning again to FIG. 1, each unit combiner, e.g., the first unit combiner 110 and the second unit combiner 120, according to some embodiments may have the structure in which windings are stacked to be overlapped with other. In other words, the windings may be concentrically stacked in the vertical direction HD as illustrated in FIG. 2, and some regions may be overlapped with each other when viewed in the vertical direction HD as illustrated In FIG. 1. For example, the length, width, and diameter of a portion (e.g., a closed loop shape in which a portion is open) corresponding to a shape, in which the windings overlap each other, may be formed substantially the same. In this case, when viewed from the vertical direction HD, the second primary winding PW2 and the fourth primary winding PW4 positioned in the top layer may be illustrated without obstruction, and portion of other windings may be obstructed or omitted from view. For example, the first unit combiner 110 may have a structure in which the first primary winding PW1, the first secondary winding SW1, and the second primary winding PW2 may be sequentially stacked in the vertical direction HD, and in the view of FIG. 1 the second primary winding PW2 at the top layer may be viewed without obstruction, while portions of the first primary winding PW1 and the first secondary winding SW1 may be obstructed by the second primary winding PW2.

The first unit combiner 110 may have a structure in which the first primary winding PW1, the first secondary winding SW1, and the second primary winding PW2 form a first loop L1. In other words, the first primary winding PW1, the first secondary winding SW1, and the second primary winding PW2 may be disposed at different layers in the vertical direction HD and form the first loop L1. The first loop L1 formed by the windings may be a closed loop when viewed in the vertical direction HD. In a case that the windings form the first loop L1, the windings may be stacked about a first central point CP1 of the closed loop in a plan view.

Likewise, the second unit combiner 120 may have a structure in which the third primary winding PW3, the second secondary winding SW2, and the fourth primary winding PW4 may be sequentially stacked in the vertical direction HD and form a second loop L2. In other words, the third primary winding PW3, the second secondary winding SW2, and the fourth primary winding PW4 may be disposed at different layers in the vertical direction HD and form the second loop L2. The second loop L2 formed by the windings may be a closed loop when viewed in the vertical direction HD. In a case that the windings form the second loop L2, the windings may be stacked about a second central point CP2 of the closed loop in a plan view.

The first loop L1 and the second loop L2 may be disposed not to be overlapped each other when viewed from the vertical direction HD. For example, the first loop L1 and the second loop L2 may be disposed adjacent to each other in the third direction when viewed from the vertical direction HD.

According to some embodiments, the windings of each unit combiner may have a structure in which the windings overlap each other, and the combiner 100 may have an improved coupling factor. The coupling factor of the combiner 100 may be improved in a case where the primary and secondary windings of each unit combiner are fully overlapped with each other in plan view as illustrated in FIG. 1. For example, a width of each winding in plan view may be the same.

According to some embodiments, the primary windings may each include an open end portion. In this case, the open end portions of the primary windings may extend toward the input terminal (that is, the first direction D1). Specifically, the open end portion of the first primary winding PW1 may extend toward the first input terminal and include a first open end portion OE1 to which a first input signal may be applied. The second primary winding PW2 may extend toward the second input terminal and include a second open end portion OE2 to which a second input signal may be applied. The third primary winding PW3 may extend toward a third input terminal and include a third open end portion OE3 to which a third input signal may be applied. The fourth primary winding PW4 may extend toward a fourth input terminal and include a fourth open end portion OE4 to which a fourth input signal may be applied.

The first secondary winding SW1 may include a (1-1)-th end portion E1-1 and a (1-2)-th end portion E1-2. In the first secondary winding SW1, the (1-2)-th end portion E1-2 may be disposed opposite to the (1-1)-th end portion E1-1. The second secondary winding SW2 may include a (2-1)-th end portion E2-1 and a (2-2)-th end portion E2-2. In the second secondary winding SW2 may the (2-2)-th end portion E2-2 may be disposed opposite to the (2-1)-th end portion E2-1. The (1-1)-th end portion E1-1 and the (1-2)-th end portion E1-2 may be open end portions of the first secondary winding SW1, and the (2-1)-th end portion E2-1 and the (2-2)-th end portion E2-2 may be open end portions of the second secondary winding SW2.

The (1-1)-th end portion E1-1 and the (2-1)-th end portion E2-1 may be connected to the output terminal. The (1-2)-th end portion E1-2 and the 2-2-th end portion E2-2 may be connected to each other through the third secondary winding SW3. In other words, the third secondary winding SW3 may connect the (1-2)-th end portion E1-2 to the 2-2-th end portion E2-2. Accordingly, when viewed from the output terminal, two parallel combiners, including the first unit combiner 110 and the second unit combiner 120, may be connected to each other in series.

According to some embodiments, the first primary winding PW1 may include a second supply end portion SE2 extending toward the output terminal in the second direction D2 to receive a supply voltage, the second primary winding PW2 may include a first supply end portion SE1 extending toward the output terminal to receive the supply voltage, the third primary winding PW3 may include a fourth supply end portion SE4 extending toward the output terminal to receive the supply voltage, and the fourth primary winding PW4 may include a third supply end portion SE3 extending toward the output terminal to receive the supply voltage.

As illustrated, each supply end portion may be formed extending toward the output terminal, and each open end portion may be formed extending toward an input terminal.

According to some embodiments, the combiner 100 of the present disclosure may have a three-dimensional stack parallel-series structure formed by connecting the first unit combiner 110 and the second unit combiner 120 to each other in series, each unit combiner having a structure including windings connected in parallel and stacked. The combiner 100 may have a high coupling factor and a low passive element loss. In addition, the combiner 100 a tuned impedance to an input terminal through a parallel-series structure. A component, such as a power amplifier, connected to the input terminal may operate with high output power/high efficiency.

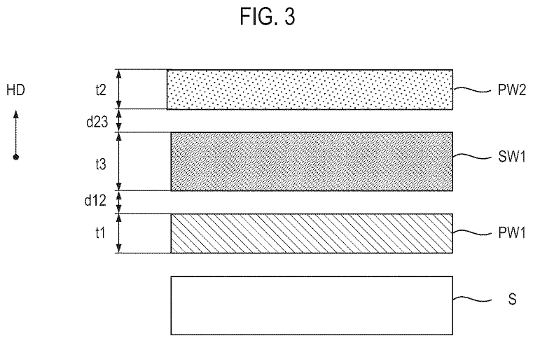

FIG. 3 is a view illustrating the stack structure of a unit combiner according to some embodiments.

Referring to FIG. 3, according to some embodiments, unit combiners, such as the first unit combiner 110 and the second unit combiner 120 of FIG. 1, may be disposed on a semiconductor substrate S. For example, the unit combiner may be fabricated through a complementary metal-oxide semiconductor (CMOS) process.

For example, the first primary winding PW1, the first secondary winding SW1, and the second primary winding PW2 may be sequentially stacked on the semiconductor substrate S in the vertical direction HD. Although FIG. 3 illustrates windings of the first unit combiner 110 (see FIG. 2), embodiments described with reference to FIG. 3 may be applied to the second unit combiner 120 including the third primary winding SW3, the second secondary winding SW2, and the fourth primary winding PW4. A ground electrode may be formed at a lower portion of the semiconductor substrate S.

In addition, an interlayer insulating layer may be interposed between the semiconductor substrate S and the first primary winding PW1, between the first primary winding PW1 and the first secondary winding SW1, and/or between the first secondary winding SW1 and the second primary winding PW2. The interlayer insulating layer may be formed of silicon oxide (SiOₓ), silicon oxynitride (SiOₓN_{y}), silicon nitride (SiNₓ), germanium oxynitride (GeOₓN_{y}), germanium silicon oxide (GeSiₓO_{y}), or a material having a high dielectric constant. The material having the high dielectric constant may include hafnium oxide (HfOₓ), zirconium oxide (ZrOₓ), aluminum oxide (AlOₓ), tantalum oxide (TaOₓ), hafnium silicate (HfSiₓ), or zirconium silicate (ZrSix). However, embodiments of the present disclosure are not limited thereto, and other materials may be used for the interlayer insulating layer. In addition, according to embodiments, the interlayer insulating layer may be formed in a multi-layer structure including at least two different materials. Further, different interlayer insulating layers may be formed of different materials.

According to some exemplary embodiments, in a unit combiner fabricated through a semiconductor fabricating process as described herein, the first primary winding PW1, the first secondary winding SW1, and the second primary winding PW2 may be disposed at different metal wiring layers among a plurality of metal wiring layers included in the semiconductor device. For example, in a semiconductor device including at least three stacked metal wiring layers, wherein the first secondary winding SW1 may be formed at the intermediate metal wiring layer, the first primary winding PW1 may be formed at the lower metal wiring layer, and the second primary winding PW2 may be formed at the upper metal wiring layer.

According to some embodiments, the first primary winding PW1, the second primary winding PW2, and the first secondary winding SW1 may include a conductive material. For example, the conductive material may be formed by using a metal such as copper, tungsten, titanium, or aluminum, or may be formed by using polysilicon, a metal, and/or a metal compound.

According to some embodiments, the first primary winding PW1 and the first secondary winding SW1 may include the same conductive material, and the first primary winding PW1 and the second primary winding PW2 may include mutually different conductive materials. However, embodiments of the present disclosure are not limited thereto. The conductive material included in the first primary winding PW1, the second primary winding PW2, and the first secondary winding SW1 may be varied according to embodiments.

According to some embodiments, a thickness t3 of the first secondary winding SW1 may be thicker than the thickness t1 of the first primary winding PW1 and a thickness t2 of the second primary winding PW2, as illustrated. The first primary winding PW1 and the second primary winding PW2 may be magnetically coupled in the vertical direction in a case that a thickness t3 of the first secondary winding SW1 may be thicker than the thickness t1 of the first primary winding PW1 and a thickness t2 of the second primary winding PW2.

According to some embodiments, the thickness t1 of the first primary winding PW1 may be substantially the same as the thickness t2 of the second primary winding PW2. In addition, a first distance d12 between the first secondary winding SW1 and the first primary winding PW1 may be substantially equal to a second distance d23 between the first secondary winding SW1 and the second primary winding PW2 may be substantially the same.

In an embodiment, the first distance d12 between the first secondary winding SW1 and the first primary winding PW1 may be a thickness of a first interlayer insulating layer, and the second distance d23 between the first secondary winding SW1 and the second primary winding PW2 may be a thickness of a second interlayer insulating layer.

As described herein, when the thickness t1 of the first primary winding PW1 and the thickness t2 of the second primary winding PW2 are formed to be equal to each other, and the first distance d12 and the second distance d23 are formed to be equal to each other, the symmetry of the unit combiner may be more effectively implemented. However, embodiments of the present disclosure are not limited thereto. According to an embodiment, the thickness t1 of the first primary winding PW1 may be different from the thickness t2 of the second primary winding PW2, or the first distance d12 and the second distance d23 may be different from each other.

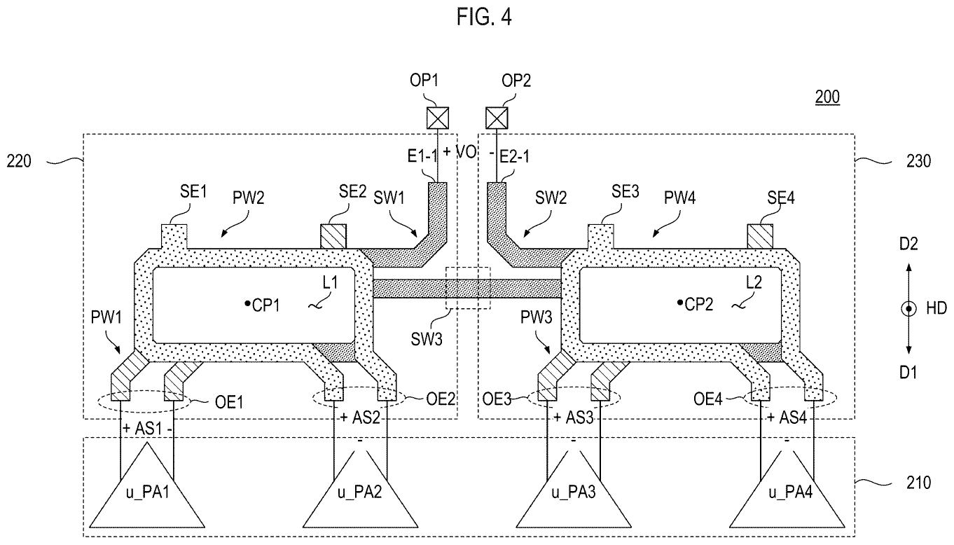

FIG. 4 illustrates a power amplifier according to some embodiments. Hereinafter, duplicative descriptions of components, elements, or functions described herein may be omitted or simplified.

Referring to FIG. 4, the power amplifier 200 according to some embodiments may include a power amplification stage 210 and a combiner.

The power amplification stage 210 may be configured to output a plurality of amplified signals by amplifying the power of the input signal. The power amplification stage 210 may include a plurality of unit PA cells. For example, the power amplification stage 210 may include first to fourth unit PA cells u_PA1 to u_PA4. An input terminal of each unit PA cell may receive an input signal through a pair of differential lines, and an output terminal of each unit PA cell may output an amplified signal through a pair of differential lines. The output terminal of each unit PA cell may be connected to a relevant first primary winding PW1.

In addition, each unit PA cell may receive an input signal through a single line and output an amplified signal through a single line.

The combiner may be connected to the output terminal of the power amplification stage 210. The combiner according to some embodiments may include a first unit combiner 220 and a second unit combiner 230. In the first unit combiner 220, the first primary winding PW1 may be connected to a first unit PA cell u_PA1, and the second primary winding PW2 may be connected to the second unit PA cell u_PA2. For example, a first open end portion OE1 may be connected to the first unit PA cell u_PA1, and a second open end portion OE2 may be connected to the second unit PA cell u_PA2. The first primary winding PW1 may receive a first amplified signal AS1 output from the first unit PA cell u_PA1, and the second primary winding PW2 may receive a second amplified signal AS2 output from the second unit PA cell u_PA2.

The (1-1)-th end portion E1-1 of the first secondary winding SW1 may be connected to a load terminal. The (1-1)-th end portion E1-1 may be connected to a first output port OP1 included in the load terminal. The first secondary winding SW1 may provide a first output signal to the load terminal by combining the first amplified signal AS1 and the second amplified signal AS2 received from each primary winding of the first unit combiner 220. The first primary winding PW1, the second primary winding PW2, and the first secondary winding SW1 may be stacked in the vertical direction HD, and may form the first loop L1 about the central point CP1.

In the second unit combiner 230, the third primary winding PW3 may be connected to a third unit PA cell u_PA3, and the fourth primary winding PW4 may be connected to a fourth unit PA cell u_PA4. For example, a third open end portion OE3 may be connected to the third unit PA cell u_PA3, and a fourth open end portion OE4 may be connected to the fourth unit PA cell u_PA4. The third primary winding PW3 may receive a third amplified signal AS3 output from the third unit PA cell u_PA3, and the fourth primary winding PW4 may receive a fourth amplified signal AS4 output from the fourth unit PA cell u_PA4.

The (2-1)-th end portion E2-1 of the secondary winding SW2 may be connected to the load terminal. The (2-1)-th end portion E2-1 may be connected to a second output port OP2 included in the load terminal. The second secondary winding SW2 may provide a second output signal by combining the third amplified signal AS3 and the fourth amplified signal AS4 received from each primary winding of the second unit combiner 230. The third primary winding PW3, the fourth primary winding PW4, and the second secondary winding SW2 may be stacked in the vertical direction HD, and may form the second loop L2 about the center point CP2.

The third secondary winding SW3 may connect the first secondary winding SW1 and the second secondary winding SW2, such that the first unit combiner 220 and the second unit combiner 230 may be connected to each other in series. Accordingly, the first secondary winding SW1, the second secondary winding SW2, and the third secondary winding SW3 may be coupled in the form of a secondary winding to provide a third output signal VO, which may be obtained by combining the first output signal and the second output signal, to the load terminal.

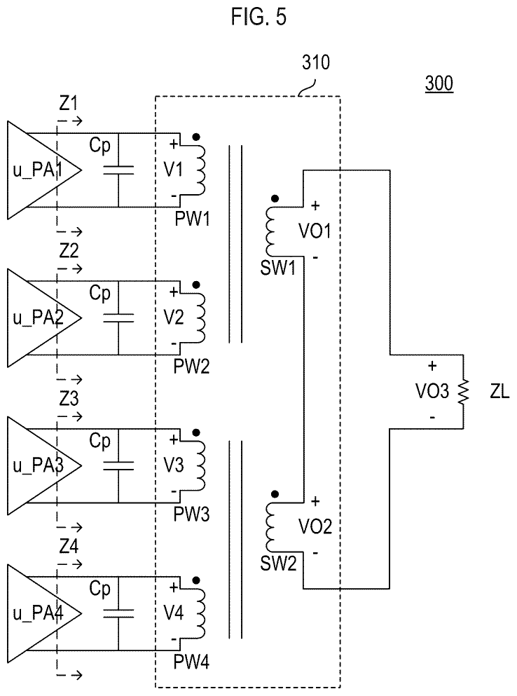

FIG. 5 illustrates an equivalent circuit of the power amplifier illustrated in FIG. 4.

Referring to FIG. 5, in the power amplifier 300, signals amplified from the unit PA cells may be applied to primary windings of the combiner 310. For example, the primary windings of FIG. 5 may correspond to the primary windings of FIGS. 1 to 4 described above.

The applied amplified signals may be combined and provided on the secondary side. For example, the first output signal VO1 obtained by combing the first amplified signal V1 and the second amplified signal V2 may be applied to the first secondary winding SW1, and a second output signal VO2 obtained by combing the third amplified signal V3 and the fourth amplified signal V4 may be applied to the second secondary winding SW2. For example, the first secondary winding SW1 and the second secondary winding SW2 may correspond to the secondary windings of FIGS. 1 to 4 described above.

As described herein, as the first unit combiner 220 and the second unit combiner 230 of FIG. 4 may be connected in series to each other through the third secondary winding SW3, the third output signal VO3 applied at the load terminal ZL may be defined as the sum of the first output signal VO1 and the second output signal VO2.

According to some embodiments, a parasitic capacitor component Cp may be present at each output terminal of the first to fourth unit PA cells u_PA1 to u_PA4 of the power amplifier 300. The parasitic capacitor component Cp may further degrade the performance of the unit PA cell in a high frequency band such as a millimeter wave spectrum.

Impedances, which are the input impedances Z1 to Z4 of the load terminal, viewed from the output terminal of each unit PA cell may be defined based on the parasitic capacitor component Cp and the inductance component of the combiner 310. According to some embodiments, the primary and secondary windings may be implemented to have an inductance component that may substantially cancel the parasitic capacitor component Cp. In particular, in a combiner 310 according to the present disclosure having a stacked parallel-series structure, the parasitic capacitor component Cp may be substantially canceled, and the parallel resistance component may be maintained in the input impedances Z1 to Z4.

According to some embodiments, the combiner 310 may provide a high coupling factor and a low passive element loss to the power amplification stage through the three-dimensional stacked parallel-series structure formed by connecting unit combiners to each other in series, each unit combiner having a structure in which windings may be connected to each other in parallel and stacked. In addition, the combiner 310 may substantially cancel a parallel reactance component and leave a parallel resistance component at the load terminal through the stacked parallel-series structure, thereby providing the tuned impedance. Accordingly, the unit PA cell may operate with higher output power/high efficiency by receiving the lower passive element loss and the tuned impedance through the combiner 310.

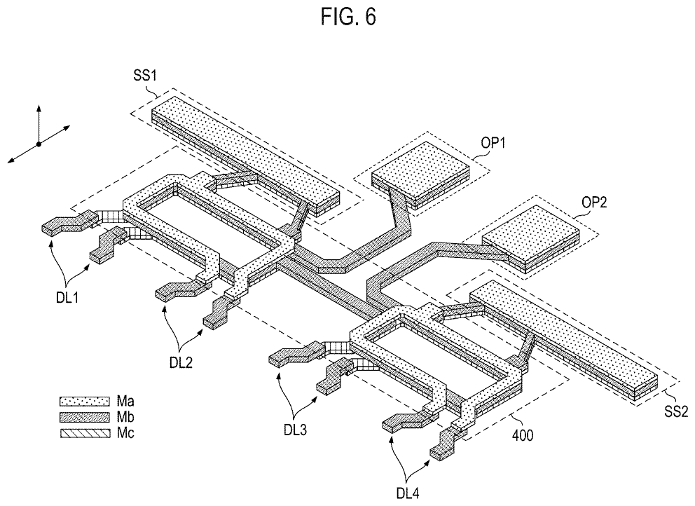

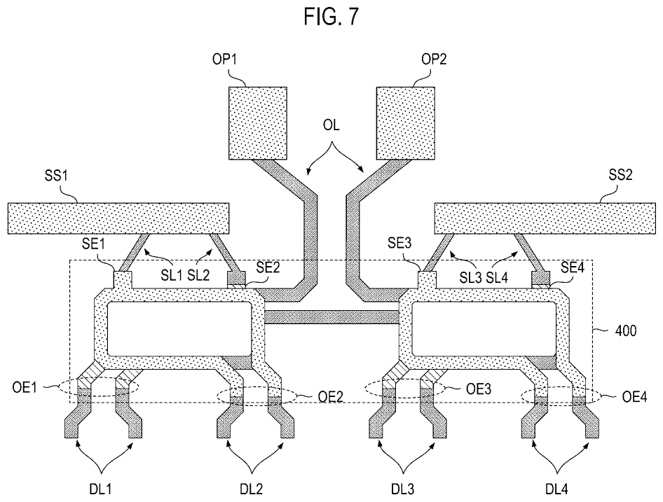

FIG. 6 is a perspective view of a metal layer structure including a combiner according to some embodiments. FIG. 7 is a plan view illustrating a metal layer structure of FIG. 6.

Referring to FIG. 6 and FIG. 7, a combiner 400 according to some embodiments may have a structure in which the first primary winding PW1 (or the third primary winding PW3), the first secondary winding SW1 (or the second secondary winding SW2), and the third primary winding PW3 (or the fourth primary winding PW4) are sequentially stacked according to some embodiments. The first primary winding (or the second primary winding) may include a first metal Ma, the first secondary winding (or the second secondary winding) may include a second metal Mb, and the third primary winding (or the fourth primary winding) may include a third metal Mc. In other words, the first metal Ma, the second metal Mb, and the third metal Mc may be sequentially stacked in the vertical direction HD.

According to some embodiments, the first to fourth open end portions OE1 to OE4 may be formed in the primary windings of the combiner 400, and a plurality of pairs of differential lines formed of the second metal Mb may be connected to the first to fourth open end portions OE1 to OE4. The plurality of pairs of differential lines may connect the output terminal of the unit PA cell to the combiner 400. For example, the first open end portion OE1 may be connected to a first pair of differential lines DL1, the second open end portion OE2 may be connected to a second pair of differential lines DL2, the third open end portion OE3 may be connected to a third pair of differential lines DL3, and the fourth open end portion OE4 may be connected to a fourth pair of differential lines DL4. In this case, the first pair of differential lines DL1 and the third pair of differential lines DL3 may be disposed on the first open end portion OE1 and the third open end portion OE3 according to the stacking sequence, and the second open end portion OE2 and the fourth open end portion OE4 may be disposed on the second pair of differential lines DL2 and the fourth pair of differential lines DLA.

According to some embodiments, first to fourth supply end portions SE1 to SE4 may be formed on primary windings of the combiner 400, and a plurality of supply lines including the second metal Mb may be connected to the first to fourth supply ends SE1 to SE4. The plurality of supply lines may connect the combiner 400, the first supply stage SS1, and the second supply stage SS2. The first supply stage SS1 and the second supply stage SS2 may have a structure in which the first metal Ma, the second metal Mb, and the third metal Mc are sequentially stacked.

For example, the first supply line SL1 may connect the first supply end portion SE1 to a first supply stage SS1, the second supply line SL2 may connect the second supply end portion SE2 to the first supply stage SS1, the third supply line SL3 may connect the third supply end portion SE3 to the second supply stage SS2, and the fourth supply line SL4 may connect the fourth supply end portion SE4 to the second supply stage SS2. In this case, the first supply end portion SE1 and the third supply end portion SE3 may be disposed on the first supply line SL1 and the third supply line SL3, respectively, and the second supply line SL2 and the fourth supply line SL4 may be disposed on the second supply end portion SE2 and the fourth supply end portion SE4, respectively, in the stacking order.

According to some embodiments, a pair of output lines OL including the second metal Mb may be connected to secondary windings (the first and second windings described herein) of the combiner 400. The pair of output lines OL may connect the combiner 400 to the first and second output ports OP1 and OP2. The first and second output ports OP1 and OP2 may have structures in which the first metal Ma, the second metal Mb, and the third metal Mc are sequentially stacked.

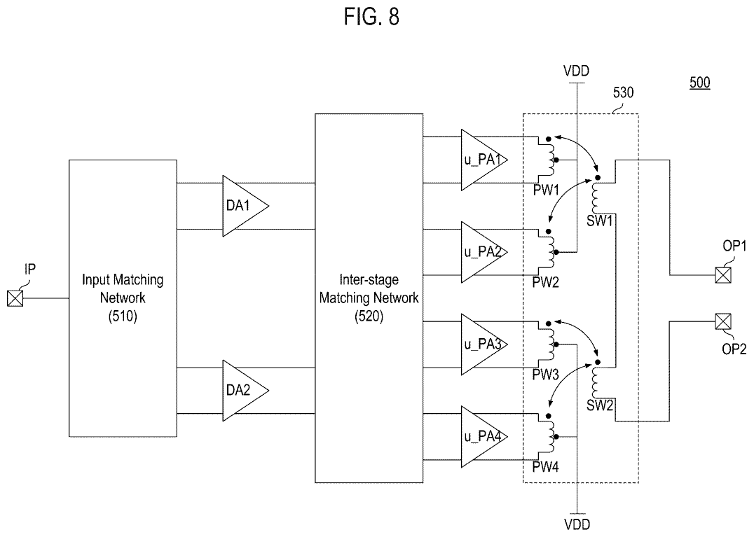

FIG. 8 illustrates a power amplifier according to some embodiments.

Referring to FIG. 8, a power amplifier 500 according to some embodiments may include an input matching network 510, a plurality of driving amplifiers DA1 and DA2, a stage matching network 520, a plurality of unit PA cells u_PA1 to u_PA4, and a combiner 530.

The input matching network 510 may be connected between an input port IP and input terminals of the plurality of driving amplifiers DA1 and DA2, and may be configured to provide impedance matching to the input terminals of the plurality of driving amplifiers DA1 and DA2.

The plurality of driving amplifiers DA1 and DA2 may operate to provide a high gain to the power amplifier 500 by forming a two-stage structure together with the plurality of unit PA cells u_PA1 to u_PA4. For example, the first driving amplifier DA1 may be connected to a transmit path including the first unit PA cell u_PA1 and the second unit PA cell u_PA2, and the second driving amplifier DA2 may be connected to a transmit path including the third unit PA cell u_PA3 and the fourth unit PA cell u_PA4.

The stage matching network 520 may be connected between the output terminals of the plurality of driving amplifiers DA1 and DA2 and the input terminals of the plurality of unit PA cells u_PA1 to u_PA4, and may be configured to provide impedance matching between a driving amplification stage and a power amplification stage.

A plurality of unit PA cells u_PA1 to u_PA4 may be connected to the stage matching network 520 to perform power amplification. The amplified signal may be provided to the output ports OP1 and OP2 through the combiner 530. The combiner 530 may be implemented according to some embodiments (for example, FIGS. 1 to 7), and may have a structure in which a first unit combiner, which includes a first primary winding PW1, the second primary winding PW2, and the first secondary winding SW1 connected in parallel, is connected to a second unit combiner, which includes the third primary winding PW3, the fourth primary winding PW4, and the second secondary winding SW2 connected to each other in parallel, in series. A driving voltage VDD may be applied to the first to fourth primary winding PW1 to PW4 included in the combiner 530. According to some embodiments, the driving voltage VDD may be commonly applied to the first primary winding PW1 and the second primary winding PW2, or commonly applied to the third and fourth primary winding PW3 and the fourth primary winding PW4 through a plurality of supply lines and supply stages as illustrated in FIG. 6 and FIG. 7.

According to some embodiments, the driving amplifier and power amplifier described herein may include a neutralized capacitor for reverse blocking.

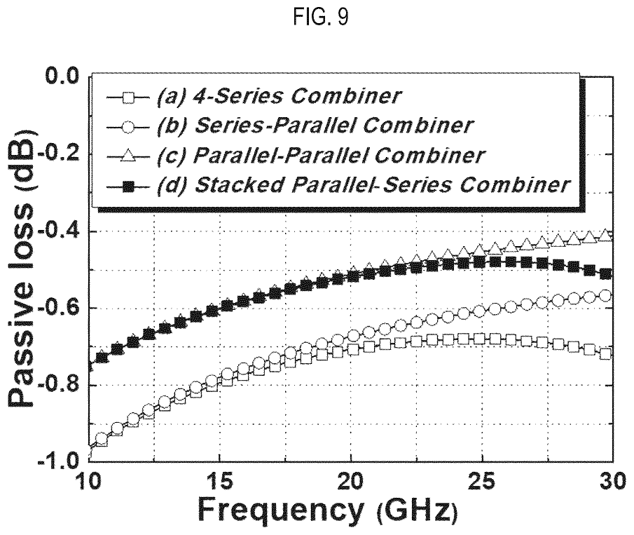

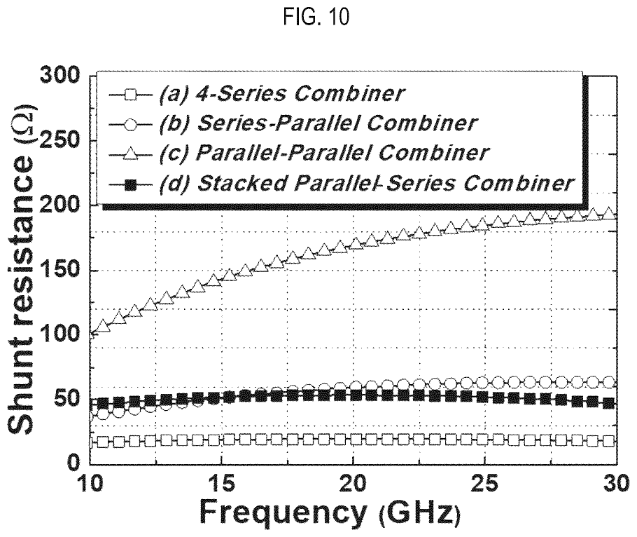

FIG. 9 illustrates a simulation result for the passive element loss of a combiner according to some embodiments. FIG. 10 illustrates a simulation result for a parallel resistance of a combiner according to some embodiments.

FIG. 9 and FIG. 10 illustrate the simulation results of the passive element loss and the parallel resistance with respect to the structures of a series-series combiner (i.e. 4-series combiner), a series-parallel combiner, and a parallel-parallel combiner, in addition to a stacked parallel-series combiner according to an embodiment of the present disclosure. Although the structure of the parallel-parallel combiner shows a relatively low passive element loss, the structure of the parallel-parallel combiner shows a relatively high input impedance at an input terminal to reduce the output power. It may be recognized from FIG. 10 that the structure of the parallel-parallel combiner among all structures shows a relatively high parallel resistance.

For the parallel resistance, the parallel resistance of the series-parallel combiner and the structure of the stacked parallel-series combiner may provide the tuned impedance for high output/high efficiency. In particular, the stacked parallel-series combiner structure may have a low passive element loss. Accordingly, it may be seen that the stacked parallel-series combiner according to some embodiments of the present disclosure may be suitable in terms of passive element loss and input impedance (i.e., parallel resistance).

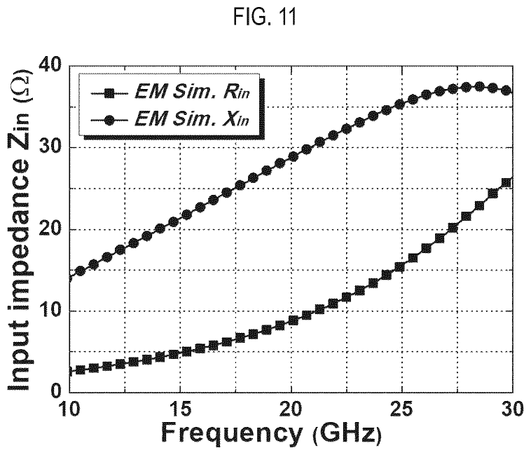

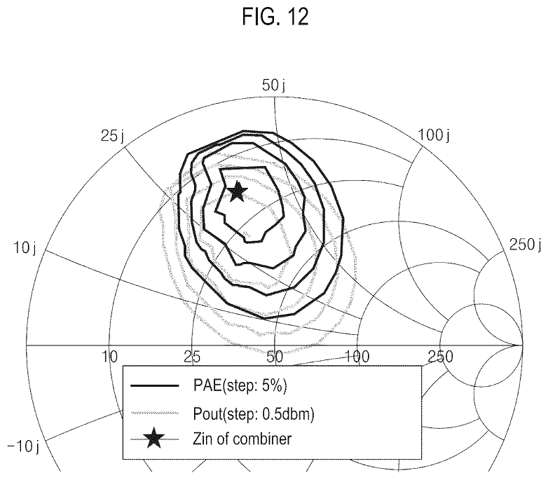

FIG. 11 illustrates a simulation result for an input impedance of a combiner according to some embodiments. FIG. 12 illustrates a load-pull simulation result according to some embodiments.

Referring to FIG. 11, for example, when a target frequency is set to 26 GHz, the input impedance Zin of the combiner was measured to be about 17.5+j36.4, where j is an imaginary component √(−1). That is, at the target frequency of 26 GHz, the reactance Xin and the resistance Rin of the combiner are about 17.5Ω and 36.4Ω, respectively. Referring to a load-pull simulation result of FIG. 12 for the relevant input impedance, the input impedance may be matched to a maximum power added efficiency (PAE) point, and a high output power may be determined.

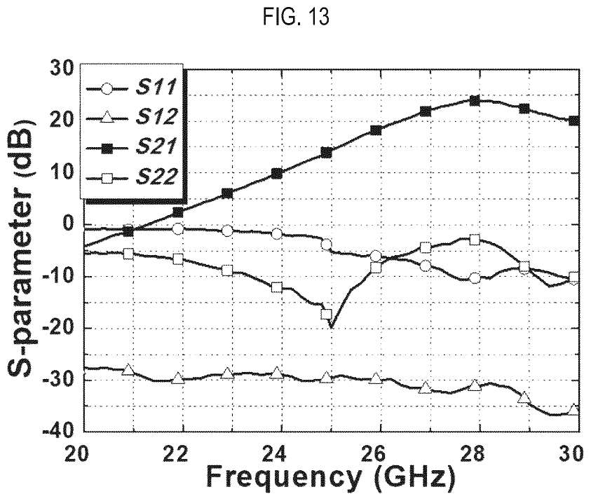

FIG. 13 illustrates a result of an S-parameter of the power amplifier according to some embodiments. FIG. 14 illustrates a result of a gain and a PAE of the power amplifier at a target frequency according to some embodiments.

Referring to FIG. 13 and FIG. 14, the power amplifier shows a gain of about 18.6 dB (see the S21 parameter) at a target frequency of about 26 GHz. In addition, the power amplifier shows the maximum output power of about 26.1 dBm and a maximum PAE of about 37.3%. Accordingly, the stacked parallel-series combiner according to embodiments of the present disclosure may allow the power amplifier to operate with high output power/high efficiency.

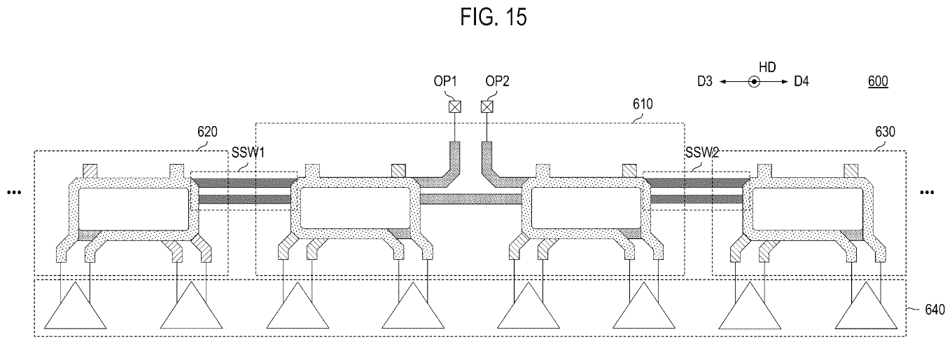

FIG. 15 illustrates a power amplifier according to some embodiments.

Referring to FIG. 15, a power amplifier circuit 600 according to some embodiments a combiner 610 formed by connecting two unit combiners in series, each unit combiner including primary and secondary windings connected in parallel, and may include a unit combiner to be connected in series. Accordingly, a power amplifier may be additionally coupled. The combiner 610 may be substantially similar to the combiner 100 described with reference to FIG. 1, and a duplicative description thereof may be omitted or simplified.

According to some embodiments, when additional unit combiners may be connected to the combiner 610 as illustrated in FIG. 15. The additional unit combiners may be referred to as a third unit combiner 620 and a fourth unit combiner 630. The third unit combiner 620 may be connected to the combiner 610 in the third direction D3 perpendicular to the vertical direction HD, and the fourth unit combiner 630 may be connected to the combiner 610 in a fourth direction D4 symmetrical to the third direction D3.

The third unit combiner 620 may be connected to the combiner 610 through a first series secondary winding SSW1, and the fourth unit combiner 630 may be connected to the combiner 610 through a second series secondary winding SSW2. According to some embodiments, the first series secondary winding SSW1 may extend from the first secondary winding (e.g., the secondary winding SW1 and SW2 of FIG. 1 and FIG. 2) included in the combiner 610 in the third direction D3, and the second series secondary winding SSW2 may extend from the second secondary winding (e.g., the secondary winding of FIG. 1 and FIG. 2) included in the combiner 610 in the fourth direction D4. Accordingly, the first series secondary winding SSW1 and the second series secondary winding SSW2 may be disposed at the same layer as the secondary winding described herein.

According to some embodiments, the power amplifier circuit 600 of FIG. 15 may include additional unit PA cells connected to the third unit combiner 620 and the fourth unit combiner 630 additionally connected in series, in addition to the unit PA cells basically connected to the combiner 610. Accordingly, the power amplification stage may include additional unit PA cells in number equal to the number of the unit combiners additionally added. Further, in addition to the third unit combiner 620 and the fourth unit combiner 630, additional unit combiners may be connected in series.

Accordingly, according to embodiments described herein, additional unit combiners may be connected to the combiner 610 in series. Accordingly, an output power (e.g., a maximum output power) of a signal output through the first output port OP1 and the second output port OP2 connected to the combiner may be increased.

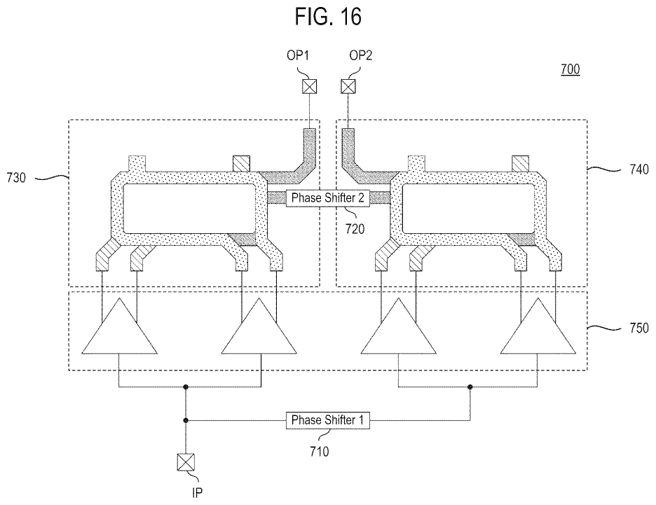

FIG. 16 illustrates a power amplifier including a phase shifter according to some embodiments.

Referring to FIG. 16, a power amplifier 700 according to some embodiments may further include a first phase shifter 710 and a second phase shifter 720. The first phase shifter 710 may be connected to an input port IP and an input terminal of the power amplification stage 750 to shift an input signal of the power amplification stage 750 by a specific phase. The second phase shifter 720 may connect the (1-2)-th end portion opposite to the (1-1)-th end portion connected to the first output port OP1 in the first secondary winding, and connect the (2-2)-th end portion opposite to the (2-1)-th end portion connected to the second output port OP2 in the second secondary winding, which is similar to the third secondary winding (e.g., the third secondary winding SW3 of FIG. 4). For example, the second phase shifter 720 may be designed based on the third secondary winding described herein. The second phase shifter 720 may be configured to shift an output signal corresponding to an input signal by a specific phase. For example, the specific phase may be 90 degrees.

According to some embodiments, the length of the third secondary winding for connecting the unit combiners 730 and 740 may be designed based on the size of each unit power amplifier cell connected to the combiner. Accordingly, according to some embodiments, the third secondary winding may be designed as the second phase shifter 720.

According to some embodiments, the second phase shifter 720 may be disposed at the same layer as the first and second secondary windings in a stack structure.

According to some embodiments, a phase shift of about 90 degrees may be performed at an input terminal and an output terminal of the power amplifier 700. In this case, the power amplifier 700 may be utilized as a Doherty power amplifier structure or a balanced power amplifier structure. The Doherty power amplifier structure may improve efficiency in a back-off region, and the balanced amplifier structure may make the performance of the output power and the power efficiency less changed by the change in the output impedance, despite of the change in the output impedance.

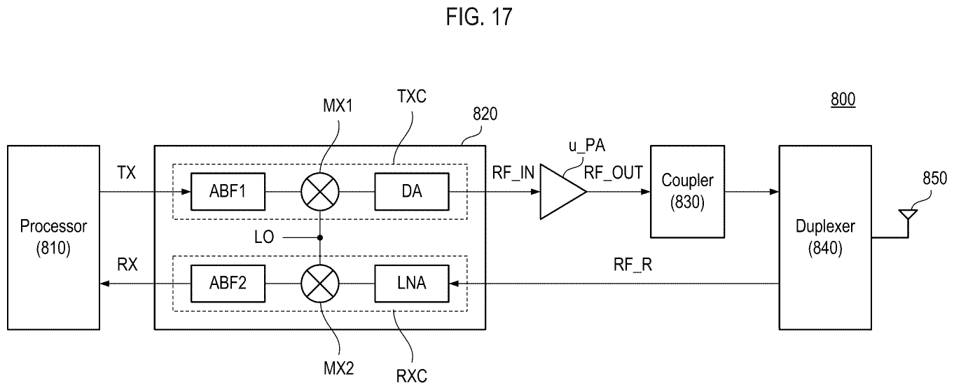

FIG. 17 illustrates a wireless communication device according to some embodiments.

Referring to FIG. 17, a wireless communication device 800 according to some embodiments may include a processor 810, a radio frequency integrated chip (RFIC) 820, a unit PA cell (PA), a combiner 830, a duplexer 840, and an antenna 850.

The processor 810 may process a baseband signal including information to be transmitted through a specific communication scheme. For example, the processor 810 may process a signal to be transmitted or received in a communication scheme, such as an Orthogonal Frequency Division Multiplexing (OFDMA) scheme, an Orthogonal Frequency Division Multiple Access (OFDMA) scheme, a Wideband Code Multiple Access (WCDMA) scheme, or a High Speed Packet Access+ (HSPA+) scheme. In addition, the processor 810 may process a baseband signal through various types of communication schemes. For example, these communication schemes may be applied to technologies for modulating or demodulating an amplitude and a frequency of a baseband signal.

The processor 810 may perform digital/analog conversion with respect to the baseband signal to generate a transmit signal TX, and output the transmit signal TX to the RFIC 820.

In addition, the processor 810 may receive a receive signal RX, which is an analog signal, from the RFIC 820. In addition, the processor 810 may perform an analog/digital-conversion operation with respect to the receive signal RX and extract a baseband signal which is a digital signal. In this case, the receive signal RX may be a differential signal including a positive signal and a negative signal.

The RFIC 820 may generate an RF input signal RF_IN by performing frequency up-conversion on the transmit signal TX or may generate the receive signal RX by performing frequency down-conversion on the RF receive signal RF_R. Specifically, the RFIC 820 may include a transmit circuit TXC for the frequency up-conversion, a receive circuit RXC for frequency down-conversion, and a local oscillator LO.

In this case, the transmit circuit TXC may include a first analog baseband filter ABF1, a first mixer MX1, and an amplifier DA. For example, the first analog baseband filter ABF1 may include a low pass filter.

The baseband filter ABF1 may filter the transmit signal TX received from the processor 810 and provide the transmit signal TX, which is filtered, to the first mixer MX1. In addition, the first mixer MX1 may perform frequency up-conversion, to convert the frequency of the transmit signal TX from a baseband to a high frequency band, based on a frequency signal provided by the local oscillator LO. Through the frequency up-conversion, the transmit signal TX may be provided to the amplifier DA as the RF input signal RF_IN, and the amplifier DA may primarily amplify the RF input signal RF_IN to provide the RF input signal, to the unit PA cell PA.

The unit PA cell PA may generate an RF output signal RF_OUT by secondarily amplifying the power of the RF input signal RF_IN based on the driving voltage. In addition, the unit PA cell PA may provide the generated RF output signal RF_OUT to the duplexer 840.

The receive circuit RXC may include a second analog baseband filter ABF2, a second mixer MX2, and a low-noise amplifier LNA. For example, the second analog baseband filter ABF2 may include a low pass filter.

The low noise amplifier LNA may amplify the RF receive signal RF_R provided from the duplexer 840 and provide the amplified RF receive signal RF_R to the second mixer MX2. In addition, the second mixer MX2 may perform frequency down-conversion, which converts the frequency of the receive signal RF_R from the high frequency band to the baseband, through the frequency signal provided by the local oscillator LO. Through the frequency down-conversion, the RF receive signal RF_R may be provided, as the signal RX, to the second analog baseband filter ABF2, and the second analog baseband filter ABF2 may filter the receive signal RX and provide the filtered receive signal RX to the processor 810.

For reference, the wireless communication device 800 may transmit a transmit signal through a plurality of frequency bands through a carrier aggregation (CA) scheme. In addition, to this end, the wireless communication device 800 may include a plurality of unit PA cells which power-amplify a plurality of RF input signals RF_IN corresponding to a plurality of carriers, respectively. However, according to an embodiment of the present disclosure, for the convenience of explanation, one unit PA cell PA is described by way of example.

The combiner 830 may be connected between the unit PA cell PA and the duplexer 840. The combiner 830 may be implemented based on some embodiments (for example, the combiner disclosed in FIGS. 1 to 16). The combiner 830 may have a three-dimensional stacked parallel-series structure, thereby allowing the unit PA cell PA to operate with high output/high efficiency.

The duplexer 840 may be connected to the antenna 850, which may split a transmit frequency from a receive frequency. Specifically, the duplexer 840 may split the RF output signal RF_OUT, which may be provided from the unit PA cell PA, for each frequency band and provide the split RF output signal RF_OUT to the relevant antenna 850. In addition, the duplexer 840 may provide the external signal provided from the antenna 850 to the low noise amplifier LNA of the receive circuit RXC of the RFIC 820. For example, the duplexer 840 may include a front end module with integrated duplexer (FEMiD).

For reference, the wireless communication device 800 may have a switch structure for splitting the transmit frequency and the receive frequency instead of the duplexer 840. In addition, the wireless communication device 800 may have a structure including the duplexer 840 and a switch to split the transmit frequency and the receive frequency. However, the following description according to an embodiment of the present disclosure is made for the convenience of explanation, in that the duplexer 840 to split the transmit frequency and the receive frequency is provided in the wireless communication device 800 by way of example.

The antenna 850 may transmit the RF output signal RF_OUT, which is frequency-split by the duplexer 840, to the outside, or may provide the RF receive signal RF_R, which is received from the outside, to the duplexer 840. For example, the antenna 850 may include an array antenna, but the present disclosure is not limited thereto.

For reference, the processor 810, the RFIC 820, the unit PA cell PA, and the duplexer 840 may be individually implemented in the form of an IC, a chip, or a module. In addition, the processor 810, the RFIC 820, the unit PA cell PA, and the duplexer 840 may be mounted together on a printed circuit board (PCB). However, the technical spirit of the present disclosure is not limited thereto. According to an embodiment, one or more of the processor 810, the RFIC 820, the unit PA cell PA, and the duplexer 840 may be implemented in the form of a single communication chip.

Furthermore, the wireless communication device 800 illustrated in FIG. 17 may be included in a wireless communication system using a cellular network such as a 5G system or an LTE system, or may be included in a wireless local area network (WLAN) system or any other wireless communication system. For reference, the configuration of the wireless communication device 800 illustrated in FIG. 17 is merely an embodiment, and the present disclosure is not limited thereto. For example, the configuration of the wireless communication device 800 may be variously configured according to a communication protocol or a communication scheme.

As described herein, according to the present disclosure, a stacked parallel-series combiner and a power amplifier including the stacked parallel-series combiner may be provided.

Although an embodiment of the present disclosure has been described for illustrative purposes, those skilled in the art will appreciate that various modifications, and substitutions are possible, without departing from the scope and spirit of the invention as disclosed in the accompanying claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A combiner comprising:
a first unit combiner which includes a first primary winding connected to a first input terminal, a second primary winding connected to a second input terminal, and a first secondary winding having a (1-1)-th end portion and a (1-2)-th end portion, wherein the (1-1)-th end portion is connected to an output terminal, and has a structure in which the first primary winding, the second primary winding, and the first secondary winding are stacked in a vertical direction and form a first loop;
a second unit combiner which includes a third primary winding connected to a third input terminal, a fourth primary winding connected to a fourth input terminal, and a second secondary winding having a (2-1)-th end portion and a (2-2)-th end portion, wherein the (2-1)-th end portion is connected to the output terminal, and has a structure in which the third primary winding, the fourth primary winding, and the second secondary winding are stacked in the vertical direction and form a second loop; and
a third secondary winding connected between the (1-2)-th end portion, which is opposite to the (1-1)-th end portion in the first primary winding, and the (2-2)-th end portion which is opposite to the (2-1)-the end portion in the second secondary winding.

2. The combiner of claim 1, wherein the first secondary winding is interposed between the first primary winding and the second primary winding; and
wherein the second secondary winding is interposed between the third primary winding and the fourth primary winding.

3. The combiner of claim 1, wherein the first primary winding includes a second supply end portion extending toward the output terminal to receive a supply voltage,
wherein the second primary winding includes a first supply end portion extending toward the output terminal to receive the supply voltage,
wherein the third primary winding includes a fourth supply end portion extending toward the output terminal to receive the supply voltage, and
wherein the fourth primary winding includes a third supply end portion extending toward the output terminal to receive the supply voltage.

4. The combiner of claim 1, wherein the third secondary winding is disposed at the same layer as the first secondary winding and the second secondary winding in the stack structure.

5. The combiner of claim 1, wherein the first loop and the second loop are separated in a horizontal direction with the third secondary winding disposed therebetween when viewed from the vertical direction.

6. The combiner of claim 1, wherein the first secondary winding has a thickness thicker than a thickness of the first primary winding and a thickness of the second primary winding, and
wherein the second secondary winding has a thickness thicker than a thickness of the third primary winding and a thickness of the fourth primary winding.

7. The combiner of claim 1, wherein the first primary winding includes a first open end portion extending toward the first input terminal to receive a first input signal,
wherein the second primary winding includes a second open end portion extending toward the second input terminal to receive a second input signal,
wherein the third primary winding includes a third open end portion extending toward the third input terminal to receive a third input signal, and
wherein the fourth primary winding includes a fourth open end portion extending toward the fourth input terminal to receive a fourth input signal.

8. The combiner of claim 7, wherein the first open end portion and the second open end portion are separated in a horizontal direction when viewed in the vertical direction, and
wherein the third open end portion and the fourth open end portion are separated in the horizontal direction when viewed in the vertical direction.

9. The combiner of claim 1, wherein a turn-ratio between a number of turns of the first primary winding and a number of turns of the first secondary winding is 1:1,
wherein the turn-ratio between a number of turns of the second primary winding and a number of turns of the first secondary winding is 1:1,
wherein the turn-ratio between a number of turns of the third primary winding and a number of turns of the second secondary winding is 1:1, and
wherein the turn-ratio between a number of turns of the fourth primary winding and a number of turns of the second secondary winding is 1:1.

10. The combiner of claim 1, wherein the first primary winding, the second primary winding, and the first secondary winding are spaced apart from each other in the vertical direction, and
wherein the third primary winding, the fourth primary winding, and the second secondary winding spaced apart from each other in the vertical direction.

11. A power amplifier comprising:
a power amplification stage including a first unit PA (power amplifier) cell, a second unit PA cell, a third unit PA cell, and a fourth unit PA cell; and
a combiner connected to an output terminal of the power amplification stage,
wherein the combiner includes:
a first unit combiner which includes a first primary winding connected to the first unit PA cell, a second primary winding connected to the second unit PA cell, and a first secondary winding having a (1-1)-th end portion and a (1-2)-th end portion, wherein the (1-1)-th end portion is connected to a load terminal, and has a structure in which the first primary winding, the second primary winding, and the first secondary winding are stacked in a vertical direction and form a first loop;
a second unit combiner which includes a third primary winding connected to the third amplifier, a fourth primary winding connected to the fourth unit PA cell, and a second secondary winding having a (2-1)-th end portion and a (2-2)-th end portion, wherein the (2-1)-th end portion is connected to the load terminal, and has a structure in which the third primary winding, the fourth primary winding, and the second secondary winding are stacked in the vertical direction and form a second loop; and
a third secondary winding connected between the (1-2)-th end portion, which is opposite to the (1-1)-th end portion in the first primary winding, and the (2-2)-th end portion which is opposite to the (2-1)-the end portion in the second secondary winding.

12. The power amplifier of claim 11, wherein the first primary winding receives a first amplified signal output from the first unit PA cell,
wherein the second primary winding receives a second amplified signal output from the second unit PA cell,
wherein the third primary winding receives a third amplified signal output from the third unit PA cell, and
wherein the fourth primary winding receives a fourth amplified signal output from the fourth unit PA cell.

13. The power amplifier of claim 12, wherein the first secondary winding provides a first output signal by combining the first amplified signal and the second amplified signal, and
wherein the second secondary winding provides a second output signal by combining the third amplified signal and the fourth amplified signal.

14. The power amplifier of claim 13, wherein the first secondary winding, the second secondary winding, and the third secondary winding provide a third output signal, which is obtained by combining the first output signal and the second output signal, to the load terminal.

15. The power amplifier of claim 11, wherein the (1-1)-th end portion is connected to a first output port included in the load terminal, and
wherein the (2-1)-th end portion is connected to a second output port included in the load terminal.

16. A power amplifier comprising:
a power amplification stage including a first unit PA (power amplifier) cell, a second unit PA cell, a third unit PA cell, and fourth unit PA cells;
a first phase shifter connected to an input terminal of the power amplification stage to shift an input signal from the power amplification stage by a specific phase;
a first unit combiner including a first primary winding connected to the first unit PA cell, a second primary winding connected to the second unit PA cell, and a first secondary winding having a (1-1)-th end portion and a (1-2)-th end portion, wherein the (1-1)-th end portion is connected to a load terminal, wherein the first primary winding, the second primary winding, and the first primary winding have a stack structure in a vertical direction and form a first loop;
a second unit combiner including a third primary winding connected to the third unit PA cell, a fourth primary winding connected to the fourth unit PA cell, and a second secondary winding having a (2-1)-th end portion and a (2-2)-th end portion, wherein the (2-1)-th end portion is connected to the load terminal, wherein the third primary winding, the fourth primary winding, and the second primary winding have a stack structure in the vertical direction and form a second loop; and
a second phase shifter connected between the (1-2)-th end portion, which is opposite to the (1-1)-th end portion, in the first primary winding, and the (2-2)-th end portion, which is opposite to the (2-1)-th end portion, in the second secondary winding.

17. The power amplifier of claim 16, wherein the specific phase is 90 degrees.

18. The power amplifier of claim 16, wherein the first secondary winding is interposed between the first primary winding and the second primary winding, and
wherein the second secondary winding is interposed between the third primary winding and the fourth primary winding.

19. The power amplifier of claim 16, wherein the second phase shifter is provided at the same layer as the first secondary winding and the second secondary winding in the stack structure.

20. The power amplifier of claim 16, wherein the second phase shifter is configured to shift an output signal, which corresponds to the input signal, by the specific phase.
